(19) United States
(12) Patent Application Publication
(10) Pub. No.: US 2026/0047260 A1
(43) Pub. Date: Feb. 12, 2026

(54) DISPLAY PANEL AND DISPLAY APPARATUS HAVING THE SAME

(71) Applicant: TIANMA ADVANCED DISPLAY TECHNOLOGY INSTITUTE (XIAMEN) CO., LTD., Xiamen (CN)

(72) Inventors: Peixuan CHEN, Xiamen (CN); Wenxin JIANG, Xiamen (CN); Kerui XI, Xiamen (CN)

(21) Appl. No.: 19/365,978

(22) Filed: Oct. 22, 2025

(30) Foreign Application Priority Data
Jun. 18, 2025 (CN) 202510819464.3

(51) Int. Cl. H10H 29/855

(52) U.S. Cl. CPC H10H 29/8552

(57) ABSTRACT

Provided are a display panel and a display apparatus. The display panel includes a substrate, a driving array layer provided at a side of the substrate, a light-emitting element provided at a side of the driving array layer away from the substrate and a first light-shielding layer provided at a side of the light-emitting element away from the substrate. A distance between a surface of the first light-shielding layer on a side close to the light-emitting element and a surface of the light-emitting element on a side away from the substrate is set to be greater than 0. That is, the first light-shielding layer is not in direct contact with the light-emitting element, which facilitates removing corresponding first light-shielding layer above the light-emitting element, reducing the influence of the first light-shielding layer on the light-emitting element, and improving the display effect of the display panel.

### CROSS-REFERENCE TO RELATED APPLICATION

The present application claims priority to Chinese Patent Application No. 202510819464.3, filed on Jun. 18, 2025, the content of which is incorporated herein by reference in its entirety.

### TECHNICAL FIELD

The present disclosure relates to the technical field of display, and, in particular, to a display panel and a display apparatus.

### BACKGROUND

With the development of display technology, the requirements for display products have been increased in various industries. In some display panels, a black light-shielding layer is adopted to cover the metal structure of the circuit layer to reduce the reflectivity of a screen and improve the ambient contrast and display quality of the display panel. However, during the manufacturing process, the black light-shielding layer often suffers from incomplete etching, thereby affecting the display effect of the display panel.

Therefore, the above technical problem has become a top priority at present.

### SUMMARY

In order to solve the above technical problem, embodiments of the present disclosure provides a display panel and a display apparatus to improve the display effect of the display panel.

In a first aspect, an embodiment of the present disclosure provides a display panel, including: a substrate, a driving array layer, a light-emitting element and a light-shielding layer. The driving array layer is provided at a side of the substrate. The light-emitting element is provided at a side of the driving array layer away from the substrate. The first light-shielding layer is provided at a side of the light-emitting element away from the substrate. A distance between a surface of the first light-shielding layer on a side close to the light-emitting element and a surface of the light-emitting element on a side away from the substrate is H0, and H0>0.

In a second aspect, based on the same inventive concept, an embodiment of the present disclosure provides a display apparatus, including the display panel described in the first aspect.

Compared with the prior art, the technical solutions provided by embodiments of the present disclosure have the following advantages.

The present disclosure provide a display panel and a display apparatus. The display panel includes a substrate, a driving array layer, a light-emitting element and a first light-shielding layer. The driving array layer is provided at a side of the substrate. The light-emitting element is provided at a side of the driving array layer away from the substrate. The first light-shielding layer is provided at a side of the light-emitting element away from the substrate. In the present disclosure, a distance between a surface of the first light-shielding layer on a side close to the light-emitting element and a surface of the light-emitting element on a side away from the substrate is set to be greater than 0. That is, the first light-shielding layer is not in direct contact with the light-emitting element, which facilitates the removal of the corresponding first light-shielding layer above the light-emitting element, and is conducive to reducing the influence of the first light-shielding layer on the light-emitting element, thereby improving the display effect of the display panel.

### BRIEF DESCRIPTION OF DRAWINGS

The drawings herein illustrate embodiments in accordance with the present disclosure, and, together with the specification, serve to explain the principles of the present disclosure.

To clearly illustrate the technical solutions of the embodiments of the present disclosure or the prior art, the drawings required in the embodiments or the prior art are briefly introduced below. It is appreciated that other drawings may be derived by those skilled in the art according to these drawings without any creative effort.

FIG. 1 is a schematic top view of a display panel according to some embodiments of the present disclosure;

FIG. 2 is a schematic cross-sectional view taken along AA′ in FIG. 1 of the present disclosure;

FIG. 3 is a further schematic cross-sectional view taken along AA′ in FIG. 1 of the present disclosure;

FIG. 4 is a further schematic cross-sectional view taken along AA′ in FIG. 1 of the present disclosure;

FIG. 5 is a further schematic cross-sectional view taken along AA′ in FIG. 1 of the present disclosure;

FIG. 6 is a schematic top view of a further display panel according to some embodiments of the present disclosure;

FIG. 7 is an enlarged view of an area Q in FIG. 6 of the present disclosure;

FIG. 8 is a schematic cross-sectional view taken along BB′ in FIG. 1 of the present disclosure;

FIG. 9 is a further schematic cross-sectional view taken along BB′ in FIG. 1 of the present disclosure;

FIG. 10 is a further schematic cross-sectional view taken along AA′ in FIG. 1 of the present disclosure;

FIG. 11 is a schematic cross-sectional view of a light-emitting element along CC′ in FIG. 1 of the present disclosure;

FIG. 12 is a schematic top view of a light-emitting element according to some embodiments of the present disclosure;

FIG. 13 is a schematic diagram of luminance of a light-emitting element according to some embodiments of the present disclosure;

FIG. 14 is a further schematic cross-sectional view taken along AA′ in FIG. 1 of the present disclosure;

FIG. 15 is a further schematic cross-sectional view taken along AA′ in FIG. 1 of the present disclosure;

FIG. 16 is a schematic top view of a light-emitting element and a second light-shielding layer according to some embodiments of the present disclosure;

FIG. 17 is a schematic cross-sectional view taken along DD′ in FIG. 1 of the present disclosure;

FIG. 18 is a further schematic cross-sectional view taken along BB′ in FIG. 1 of the present disclosure;

FIG. 19 is a further schematic cross-sectional view taken along CC′ in FIG. 1 of the present disclosure;

FIG. 20 is a further schematic cross-sectional view taken along CC′ in FIG. 1 of the present disclosure;

FIG. 21 is a further schematic cross-sectional view taken along CC′ in FIG. 1 of the present disclosure;

FIG. 22 is a further schematic cross-sectional view taken along AA′ in FIG. 1 of the present disclosure; and

FIG. 23 is a schematic diagram of a display apparatus according to some embodiments of the present disclosure.

### DESCRIPTION OF EMBODIMENTS

To understand the above-mentioned purposes, features and advantages of the present disclosure, the technical solutions of the present disclosure will be further described below. It should be noted that the embodiments of the present disclosure and the features in the embodiments may be combined with each other without conflict.

In the following description, many specific details are set forth to fully understand the present disclosure, but the present disclosure may be implemented in other manners different from those described herein. It is apparent that the embodiments in the specification are just some, rather than all, of the embodiments of the present disclosure.

The inventors discovered during their research that in some display panels, a black light-shielding layer is adopted to cover the metal structure of the circuit layer to reduce the screen reflectivity and improve the ambient contrast and display quality of the display panel. During the manufacturing of the black light-shielding layer, a whole black light-shielding layer is usually formed on a side of the light-emitting surface of the light-emitting element, and the corresponding portion of black light-shielding layer above the light-emitting area of the light-emitting element is removed through a developing process or an ashing process. In the actual manufacturing process, it was found that the surface of the light-emitting element has many microstructures or graphic structures resulting in uneven surface, which is difficult to be removed through the developing process or the ashing process, thereby affecting the display effect. In addition, when using the ashing process to remove the black light-shielding layer, the generated black particles may contaminate the ashing chamber and the display panel, which not only affects the production yield of the display panel, but also increases the maintenance cost of the device.

Therefore, the above problem has become one of the technical problems that need to be solved urgently at this stage.

In view of this, the embodiments of the present disclosure provide a display panel and a display apparatus to improve the display effect of the display panel.

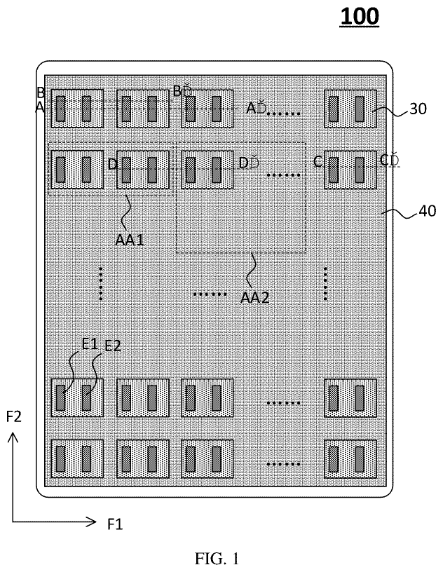

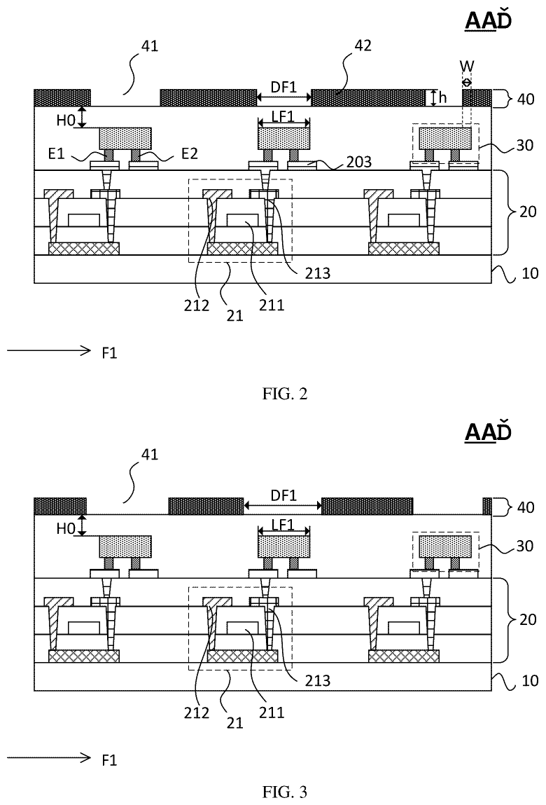

FIG. 1 is a schematic top view of a display panel according to some embodiments of the present disclosure. FIG. 2 is a schematic cross-sectional view taken along AA′ in FIG. 1 of the present disclosure. Referring to FIG. 1 and FIG. 2, an embodiment of the present disclosure provides a display panel 100, including: a substrate 10, a driving array layer 20, a light-emitting element 30 and a first light-shielding layer 40. The driving array layer 20 is provided at a side of the substrate 10. The light-emitting element 30 is provided at a side of the driving array layer 20 away from the substrate 10. The first light-shielding layer 40 is provided at a side of the light-emitting element 30 away from the substrate 10. A distance between a surface of the first light-shielding layer 40 on a side close to the light-emitting element 30 and a surface of the light-emitting element 30 on a side away from the substrate 10 is H0, and H0>0.

It should be noted that the drawings of the present disclosure are merely schematic, and will not represent the actual structure of the display panel 100. For example, many microstructures or graphic structures actually exist on the surface of the light-emitting element 30, which are not shown in the drawings. For the purpose of clear illustration, transparency is applied to certain film layers in the drawings of the present disclosure. For example, in the top view of FIG. 1, transparency is applied to the first light-shielding layer 40. Transparency is also applied to some other film layers, which will not be elaborated herein.

In an embodiment, the present disclosure provides a display panel 100, including the substrate 10, the driving array layer 20, the light-emitting element 30, and the first light-shielding layer 40. The driving array layer 20 is provided at the side of the substrate 10. The light-emitting element 30 is provided at the side of the driving array layer 20 away from the substrate 10. The light-emitting element 30 is electrically connected to the driving array layer 20, and emits light under the driving of the driving array layer 20. The driving array layer 20 includes various metal structures, and in order to cover these metal structures and reduce the reflectivity of the display panel 100, the first light-shielding layer 40 is provided at the side of the light-emitting element 30 away from the substrate 10.

It should be noted that the light-emitting element 30 is electrically connected to the driving array layer 20 through a bonding structure 203, and the bonding structure 203 serves as a connecting bridge between the driving array layer 20 and the light-emitting element 30, transmitting the signal provided by the driving array layer 20 to the light-emitting element 30.

For the display panel 100 according to an embodiment of the present disclosure, the distance between the surface of the first light-shielding layer 40 on the side close to the light-emitting element 30 and the surface of the light-emitting element 30 on the side away from the substrate 10 is H0, and H0>0. That is, the first light-shielding layer 40 is not in direct contact with the light-emitting element 30.

It should be noted that many microstructures or graphic structures exist on the surface of the light-emitting element 30. That is, the surface of the light-emitting element 30 is uneven. In the prior art, the first light-shielding layer 40 is directly manufactured on the surface of the light-emitting element 30, and the first light-shielding layer 40 is in direct contact with the light-emitting element 30. When removing the corresponding first light-shielding layer 40 above the light-emitting element 30, the first light-shielding layer 40 cannot be completely removed due to the uneven surface of the light-emitting element 30, thereby affecting the display effect. In the present disclosure, the first light-shielding layer 40 is not in direct contact with the light-emitting element 30. Such configuration is conducive to removing the first light-shielding layer 40 above the light-emitting element 30, reducing the residue of the first light-shielding layer 40, and reducing the influence of the first light-shielding layer 40 on the light-emitting element 30, thereby improving the display effect of the display panel 100.

It should also be noted that the driving array layer 20 includes a transistor 21, and the transistor 21 includes a gate 211, a source 212 and a drain 213. The control signal is input through the gate 211, the channel area between the source 212 and the drain 213 is turned on, and a path is formed between the source 212 and the drain 213. The electrical signal can be written into the drain 213 through the source 212 and the channel area.

Referring to FIG. 1 and FIG. 2 again, in some embodiments of the present disclosure, the first light-shielding layer 40 includes a plurality of first opening portions 41, and at least one of the plurality of first opening portions 41 overlaps the light-emitting element 30.

Along a first direction F1 and/or a second direction F2, a width DF1 of at least part of the first opening portions 41 is greater than a width LF1 of the light-emitting element 30; and/or, the width DF1 of at least part of the first opening portions 41 is equal to the width LF1 of the light-emitting element 30; and/or, the width DF1 of at least part of the first opening portions 41 is less than the width LF1 of the light-emitting element 30. Both the first direction F1 and the second direction F2 are parallel to a plane of the display panel 100.

In an embodiment, the first light-shielding layer 40 includes first opening portions 41, at least one of the first opening portions 41 overlaps the light-emitting element 30, and the light from the light-emitting element 30 is emitted through the first opening portions 41. The display panel 100 includes light-emitting elements 30 and first opening portions 41. The dimension relationship between the first opening portions 41 and the light-emitting elements 30 includes the following three types: first, in the first direction F1 and/or the second direction F2, the width DF1 of the first opening portions 41 is greater than the width LF1 of the light-emitting elements 30; second, in the first direction F1 and/or the second direction F2, the width DF1 of the first opening portions 41 is equal to the width LF1 of the light-emitting elements 30; and third, in the first direction F1 and/or the second direction F2, the width DF1 of the first opening portions 41 is less than the width LF1 of the light-emitting elements 30. It should be noted that in an actual display panel 100, the relationship between different light-emitting elements 30 and the first opening portions 41 may be one of the above, or a combination of two or three of the above, which are not limited thereto in the present disclosure.

In the configuration of the present disclosure, the width DF1 of at least part of the first opening portions 41 is greater than the width LF1 of the light-emitting elements 30; and/or, the width DF1 of at least part of the first opening portions 41 is equal to the width LF1 of the light-emitting elements 30; and/or, the width DF1 of at least part of the first opening portions 41 is less than the width LF1 of the light-emitting elements 30. The width DF1 of the first opening portion 41 of the display panel 100 may be greater than, equal to, or less than the width LF1 of the light-emitting elements 30. The same design may be adopted, and a differentiated design may also be adopted, which can be implemented according to actual situations, and is not limited thereto in the present disclosure.

It should be noted that the first direction F1 is parallel to the plane of the display panel 100, and may be any direction within the plane of the display panel 100. For example, it can be the direction from a first electrode E1 of the light-emitting element 30 to a second electrode E2 of the light-emitting element 30. This example is merely to illustrate, but not to limit, the present disclosure.

FIG. 3 is a further schematic cross-sectional view taken along AA′ in FIG. 1 of the present disclosure. Referring to FIG. 1 and FIG. 3, in an embodiment of the present disclosure, in the first direction F1, in the display panel 100, the widths DF1 of the first opening portions 41 are all greater than the width LF1 of the light-emitting elements 30. The dimension of the first opening portions 41 is greater than that of the light-emitting elements 30, following the same dimensional design principle. In the same display panel 100, the dimensions of the first opening portions 41 are all greater than those the light-emitting elements 30. On the one hand, the first opening portions 41 and the light-emitting elements 30 share the same dimension relationship design, which is conducive to simplifying the manufacturing of the display panel 100. On the other hand, the dimension of the first opening portions 41 is greater than that of the light-emitting elements 30, which is conducive to the light of the light-emitting element 30 passing through the first opening portions 41, thereby improving the luminance of the display panel 100.

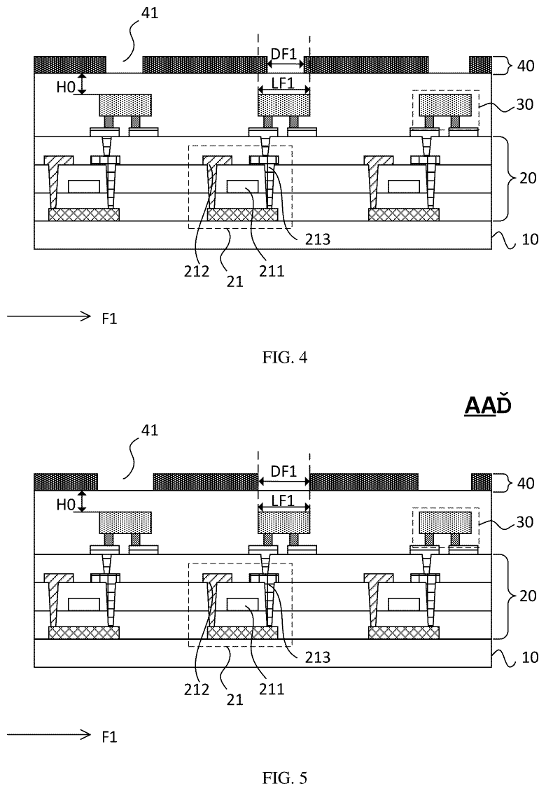

FIG. 4 is a further schematic cross-sectional view taken along AA′ in FIG. 1 of the present disclosure. Referring to FIG. 1 and FIG. 4, in an embodiment of the present disclosure, in the first direction F1, in the display panel 100, the width DF1 of the first opening portions 41 is less than the width LF1 of the light-emitting elements 30. In an embodiment, the first opening portions 41 and the light-emitting elements 30 share the same dimensional design principle, which is conducive to simplifying the manufacturing of the display panel 100. In an embodiment, the dimension of the first opening portions 41 is less than that of the light-emitting elements 30. Such configuration is conducive to the shielding of the metal structure of the driving array layer 20 by the first light-shielding layer 40, thereby reducing the reflectivity of the display panel 100 and improving the display effect of the display panel 100.

FIG. 5 is a further schematic cross-sectional view taken along AA′ in FIG. 1 of the present disclosure. Referring to FIG. 1 and FIG. 5, in an embodiment of the present disclosure, in the first direction F1, in the display panel 100, the widths DF1 of the first opening portions 41 are all equal to the width LF1 of the light-emitting elements 30. That is, the dimension of the first opening portions 41 is equal to that of the light-emitting elements 30, following the same dimensional design principle. In the same display panel 100, the dimension of the first opening portions 41 is equal to the dimension of the light-emitting elements 30. On the one hand, the dimension of the first opening portions 41 is the same as that of the light-emitting elements 30, which is conducive to simplifying the manufacturing of the display panel 100. On the other hand, the dimension of the first opening portions 41 is the same as that of the light-emitting elements 30, and the first opening portions 41 and the light-emitting element 30 completely overlap each other, which is conducive to reducing the impact on the luminous efficiency of the light-emitting elements 30. Meanwhile, the metal structure of the driving array layer 20 is shielded as much as possible, which is conducive to reducing the reflectivity.

It should be noted that in the above three embodiments, in the same display panel 100, the dimension of the first opening portions 41 is the same as that of the light-emitting elements 30, but the present disclosure is not limited to this. In the same display panel 100, the dimensions of the first opening portions 41 and the light-emitting elements 30 may also be different, which can be designed according to specific circumstances.

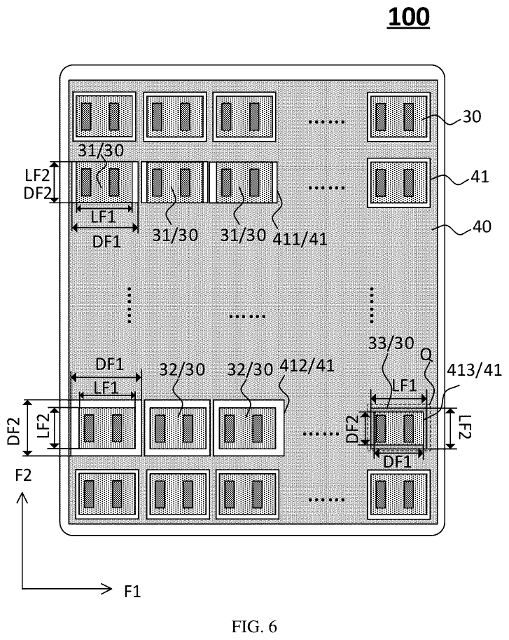

FIG. 6 is a schematic top view of a further display panel according to some embodiments of the present disclosure. Referring to FIG. 6, in an embodiment of the present disclosure, in the first direction F1, the width DF1 of at least part of the first opening portions 41 is greater than the width LF1 of the light-emitting elements 30; and in the second direction F2, the width DF2 of at least part of the first opening portions 41 is equal to the width LF2 of the light-emitting elements 30.

In an embodiment, a dimension relationship between the first opening portions 41 and the light-emitting elements 30 along different directions is provided. In the first direction F1, the width DF1 of at least part of the first opening portions 41 is greater than the width LF1 of the light-emitting elements 30; and in the second direction F2, the width DF2 of at least part of the first opening portions 41 is equal to the width LF2 of the light-emitting elements 30. Referring to FIG. 6, the light-emitting elements 31 correspond to the first opening portions 411. In the first direction F1, the width DF1 of the first opening portion 411 is greater than the width LF1 of the light-emitting element 31; and in the second direction F2, the width DF2 of the first opening portion 411 is equal to the width LF2 of the light-emitting element 31.

Referring to FIG. 6 again, in an embodiment of the present disclosure, in the first direction F1, the width DF1 of at least part of the first opening portion 41 is greater than the width LF1 of the light-emitting element 30; and in the second direction F2, the width DF2 of at least part of the first opening portion 41 is greater than the width LF2 of the light-emitting element 30.

In an embodiment, a further dimension relationship between the first opening portions 41 and the light-emitting elements 30 along different directions is provided. In the first direction F1, the width DF1 of at least part of the first opening portions 41 is greater than the width LF1 of the light-emitting elements 30; and in the second direction F2, the width DF2 of at least part of the first opening portions 41 is greater than the width LF2 of the light-emitting elements 30. The first direction F1 and the second direction F2 intersect with each other. Such configuration defines the width of the first opening portions 41 to be greater than the width of the light-emitting elements 30 in two directions, which is more conducive to the light of the light-emitting elements 30 passing through the first opening portions 41, thereby improving the luminance of the display panel 100. Referring to FIG. 6, the light-emitting elements 32 in FIG. 6 correspond to the first opening portions 412. In the first direction F1, the width DF1 of the first opening portion 412 is greater than the width LF1 of the light-emitting element 32; and in the second direction F2, the width DF2 of the first opening portion 412 is greater than the width LF2 of the light-emitting element 32.

Referring to FIG. 6 again, in an embodiment of the present disclosure, in the first direction F1, the width DF1 of at least part of the first opening portions 41 is less than the width LF1 of the light-emitting elements 30; and in the second direction F2, the width DF2 of at least part of the first opening portions 41 is less than the width LF2 of the light-emitting elements 30.

In an embodiment, a dimension relationship between the first opening portions 41 and the light-emitting elements 30 along different directions is provided. In the first direction F1, the width DF1 of at least part of the first opening portions 41 is less than the width LF1 of the light-emitting elements 30, and in the second direction F2, the width DF2 of at least part of second opening portions is less than the width LF2 of the light-emitting elements 30. The first direction F1 and the second direction F2 intersect with each other. Such configuration defines the width of the first opening portions 41 to be less than the width of the light-emitting elements 30 in two directions, further ensuring that the dimension of at least part of the first opening portions 41 of the display panel 100 is less than that of the light-emitting elements 30, which is more conducive to the first light-shielding layer 40 shielding the metal structure of the driving array layer 20, thereby reducing the reflectivity of the display panel 100. Referring to FIG. 6, the light-emitting elements 33 in FIG. 6 correspond to the first opening portions 413. In the first direction F1, the width DF1 of the first opening portion 413 is less than the width LF1 of the light-emitting element 33; and in the second direction F2, the width DF2 of the first opening portion 413 is less than the width LF2 of the light-emitting element 33.

It should be noted that, in the display panel 100 according to some embodiments of the present disclosure, the distance between the surface of the first light-shielding layer 40 on the side close to the light-emitting elements 30 and the surface of the light-emitting elements 30 on the side away from the substrate 10 is greater than 0. That is, the first light-shielding layer 40 is not in direct contact with the light-emitting elements 30, which is conducive to removing the first light-shielding layer 40 above the light-emitting elements 30, thereby reducing the influence of the first light-shielding layer 40 on the light-emitting elements 30, and further improving the display effect of the display panel 100. In an embodiment of the present disclosure, in order to reduce the reflectivity of the display panel 100, a first light-shielding portion 421 is configured to shield a part of certain regions of the light-emitting elements 30.

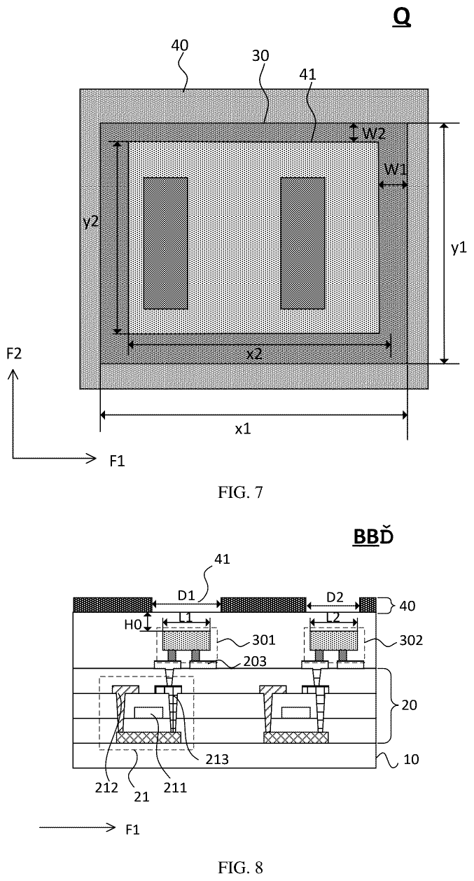

FIG. 7 is an enlarged view of an area Q in FIG. 6 of the present disclosure. Referring to FIG. 6 and FIG. 7, in an embodiment of the present disclosure, the width of the light-emitting elements 30 in the first direction F1 is x1, and the width in the second direction F2 is y1, where x1>y1; the width of the first opening portions 41 in the first direction F1 is x2, and the width in the second direction F2 is y2, where x2>y2, and x1−x2>y1−y2.

In an embodiment, the width of the light-emitting elements 30 in the first direction F1 and the width in the second direction F2 are different from each other, and the width x1 of the light-emitting elements 30 in the first direction F1 is greater than the width y1 in the second direction F2. The width of the first opening portions 41 in the first direction F1 and the width in the second direction F2 are also different from each other, and the width x2 of the first opening portions 41 in the first direction F1 is greater than the width y2 in the second direction F2. Since the width of the light-emitting elements 30 in the first direction F1 is greater than the width in the second direction F2, the shielding of the light-emitting elements 30 in the first direction F1 is greater than the shielding of the light-emitting elements 30 in the second direction F2. That is, the shielding along the long edge of the light-emitting elements 30 is greater than the shielding along the short edge of the light-emitting elements 30. Referring to FIG. 7, the shielding of the light-emitting elements 30 in the first direction F1 is greater than the shielding of the light-emitting elements 30 in the second direction F2, thus it can be concluded that (x1−x2)/2>(y1−y2)/2, and it can be further concluded that x1−x2>y1−y2. Such configuration is conducive to reducing the luminance loss of the light-emitting elements 30, and enables the first light-shielding layer 40 to effectively shield the metal structure of the driving array layer 20, thereby reducing the reflectivity of the display panel 100.

For example, the width x1 of the light-emitting elements 30 in the first direction F1 satisfies x1=25 μm, the width y1 of the light-emitting element 30 in the second direction F2 satisfies y1=15 μm, the width x2 of the first opening portions 41 in the first direction F1 satisfies x2=19 μm, and the width y2 of the first opening portions 41 in the second direction F2 satisfies y2=13 μm. In the first direction F1, the shielding width of the light-emitting elements 30 by the first light-shielding layer 40 satisfies (x1−x2)/2=3 μm; and in the second direction F2, the shielding width of the light-emitting elements 30 by the first light-shielding layer 40 satisfies (y1−y2)/2=1 μm. Thus, the shielding of the light-emitting elements 30 by the first light-shielding layer 40 in the first direction F1 is greater than the shielding of the light-emitting elements 30 by the second light-shielding layer 70 in the second direction F2.

Referring to FIG. 6 and FIG. 7 again, in some embodiments of the present disclosure, x1/y1≥x2/y2.

In an embodiment, the width of the light-emitting elements 30 in the first direction F1 is x1, and the width in the second direction F2 is y1, where x1>y1. The width of the light-emitting element 30 in the first direction F1 is greater than the width in the second direction F2. The width of the first opening portions 41 in the first direction F1 is x2, and the width in the second direction F2 is y2, where x2>y2. The width of the first opening portions 41 in the first direction F1 is greater than the width in the second direction F2. In an embodiment of the present disclosure, x1/y1>x2/y2. In this case, the shape of the first opening portions 41 and the shape of the second opening portions are not similar shapes, and the shielding of the light-emitting elements 30 by the first light-shielding layer 40 in the first direction F1 is greater than the shielding of the light-emitting elements 30 by the first light-shielding layer 40 in the second direction F2, which facilitates effectively shielding the metal structure of the driving array layer 20 by the first light-shielding layer 40, thereby reducing the reflectivity of the display panel 100. In an embodiment of the present disclosure, x1/y1=x2/y2. In this case, the shape of the first opening portions 41 and the shape of the light-emitting elements 30 are similar shapes. That is, the first light-shielding layer 40 shields the light-emitting elements 30 in proportion, and the width of the light-emitting elements 30 in the first direction F1 is greater than the width in the second direction F2. Accordingly, the width of the first opening portions 41 in the first direction F1 is set to be greater than the width in the second direction F2, and the ratio of the width of the first opening portions 41 in the first direction F1 to the width of the light-emitting elements 30 in the first direction F1 is the same as the ratio of the width of the first opening portions 41 in the second direction F2 to the width of the light-emitting elements 30 in the second direction F2. In this case, the shape of the first opening portions 41 and the shape of the second opening portions are similar shapes. Such configuration further facilitates effectively shielding the metal structure of the driving array layer 20 by the first light-shielding layer 40, thereby reducing the reflectivity of the display panel 100.

FIG. 8 is a schematic cross-sectional view taken along BB′ in FIG. 1 of the present disclosure. Referring to FIG. 1 and FIG. 8, in an embodiment of the present disclosure, the light-emitting elements 30 include a first color light-emitting element 301 and a second color light-emitting element 302, and an operating current of the first color light-emitting element 301 is greater than an operating current of the second color light-emitting element 302. In the first direction F1, the width of the first opening portion 41 corresponding to the first color light-emitting element 301 is D1, and the width of the first opening portion 41 corresponding to the second color light-emitting element 302 is D2, where D1>D2.

In an embodiment, the display panel 100 includes a plurality of light-emitting elements 30. In order to improve the color richness of the display panel 100, the light-emitting elements 30 include the first color light-emitting element 301 and the second color light-emitting element 302. The operating current of the first color light-emitting element 301 is greater than the operating current of the second color light-emitting element 302. In some embodiments of the present disclosure, the first color light-emitting element 301 is a red light-emitting element, and the second color light-emitting element 302 is a green light-emitting element. It should be noted that this example is merely to illustrate, but not to limit, the present disclosure. In this embodiment, for light-emitting elements 30 with different operating currents, the dimensions of the first opening portions 41 are designed differently. In an embodiment, the width D1 of the first opening portion 41 corresponding to the first color light-emitting element 301 is greater than the width D2 of the first opening portion 41 corresponding to the second color light-emitting element 302. That is, the width of the first opening portion 41 corresponding to the light-emitting element 30 with a higher operating current is greater than the width of the first opening portion 41 corresponding to the light-emitting element 30 with a lower operating current.

It should be noted that the operating current of the light-emitting elements 30 may affect the power consumption of the display panel 100, which satisfies Power consumption=Operating current×Voltage. It can be seen that the greater the operating current of the light-emitting elements 30 is, the higher the power consumption of the display panel 100 is. The operating current of the first color light-emitting element 301 is greater than the operating current of the second color light-emitting element 302, and the power consumption of the first color light-emitting element 301 is greater than the power consumption of the second color light-emitting element 302. In an embodiment, the width D1 of the first opening portion 41 corresponding to the first color light-emitting element 301 is set to be greater than the width D2 of the first opening portion 41 corresponding to the second color light-emitting element 302. Under the same power consumption, the luminance of the first color light-emitting element 301 is less than the luminance of the second color light-emitting element 302. By increasing the width of the first opening portion 41 corresponding to the first color light-emitting element 301, the first color light-emitting element 301 emits more light from the corresponding first opening portion 41, and by increasing width of the first opening portion 41, the luminance of the first color light-emitting element 301 is increased, which is conducive to balancing the luminance differences of different light-emitting elements 30.

In the first direction F1, the width of the first color light-emitting element 301 is L1, and the width of the second color light-emitting element 302 is L2.

Referring to FIG. 1 and FIG. 8 again, in an embodiment of the present disclosure, D1>L1 and D2>L2.

In an embodiment, the width D1 of the first opening portion 41 corresponding to the first color light-emitting element 301 is greater than the width L1 of the first color light-emitting element 301, and the width D2 of the first opening portion 41 corresponding to the second color light-emitting element 302 is greater than the width L2 of the second color light-emitting element 302. That is, the width of the first opening portions 41 is greater than the width of the light-emitting elements 30. In this way, the area of the first opening portions 41 is relatively large, which is conducive to improving the luminance of the display panel 100. Meanwhile, the width D1 of the first opening portion 41 corresponding to the first color light-emitting element 301 is greater than the width D2 of the first opening portion 41 corresponding to the second color light-emitting element 302. Under the same power consumption, since the operating current of the first color light-emitting element 301 is greater than the operating current of the second color light-emitting element 302, the luminance of the first color light-emitting element 301 is less than the luminance of the second color light-emitting element 302. By increasing the width of the first opening portion 41 corresponding to the first color light-emitting element 301, the first color light-emitting element 301 emits more light from the corresponding first opening portion 41, and by increasing the width of the first opening portion 41, the luminance of the first color light-emitting element 301 is increased, which is conducive to balancing the luminance differences of different light-emitting elements 30.

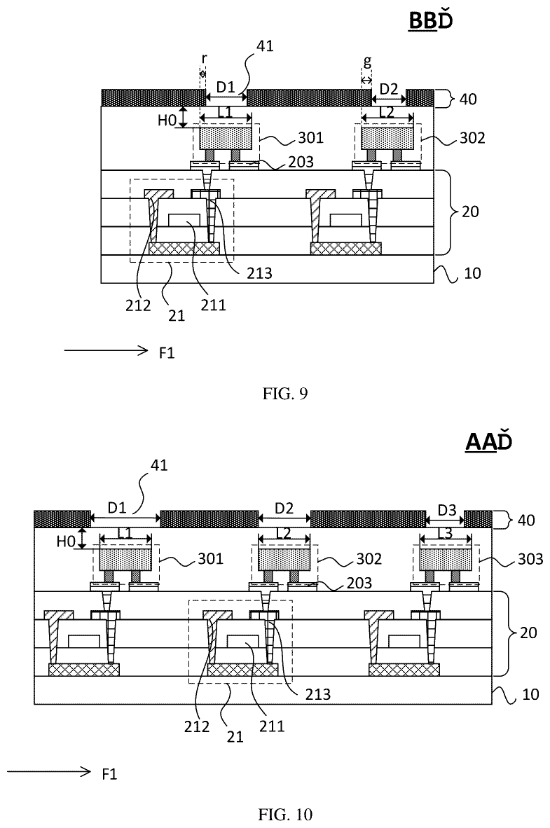

FIG. 9 is a further schematic cross-sectional view taken along BB′ in FIG. 1 of the present disclosure. Referring to FIG. 1 and FIG. 9, in an embodiment of the present disclosure, D1<L1 and D2<L2.

In an embodiment, the width D1 of the first opening portion 41 corresponding to the first color light-emitting element 301 is less than the width L1 of the first color light-emitting element 301, and the width D2 of the first opening portion 41 corresponding to the second color light-emitting element 302 is less than the width L2 of the second color light-emitting element 302. That is, the width of the first opening portions 41 is greater than the width of the light-emitting elements 30. In this way, the width of the first opening portions 41 is less than the width of the light-emitting elements 30, which is conducive shielding the metal structure of the driving array layer 20 by the first light-shielding layer 40, thereby reducing the reflectivity of the display panel 100.

FIG. 10 is a further schematic cross-sectional view taken along AA′ in FIG. 1 of the present disclosure. Referring to FIG. 1 and FIG. 10, in an embodiment of the present disclosure, the light-emitting element 30 further includes a third color light-emitting element 303, and an operating current of the third color light-emitting element 303 is less than the operating current of the second color light-emitting element 302. In the first direction F1, the width of the first opening portion 41 corresponding to the third color light-emitting element 303 is D3, and the width of the third color light-emitting element 303 is L3, where D1>L1, D2=L2 and D3<L3.

In an embodiment, the light-emitting elements 30 include the first color light-emitting element 301, the second color light-emitting element 302, and the third color light-emitting element 303. The operating current of the first color light-emitting element 301 is greater than the operating current of the second color light-emitting element 302, and the operating current of the second color light-emitting element 302 is greater than the operating current of the third color light-emitting element 303. In an embodiment, the dimension relationship between light-emitting elements 30 of different colors and the corresponding first opening portions 41 is provided. The width D1 of the first opening portion 41 corresponding to the first color light-emitting element 301 is greater than the width L1 of the first color light-emitting element 301; the width D2 of the first opening portion 41 corresponding to the second color light-emitting element 302 is equal to the width L2 of the second color light-emitting element 302; and the width D3 of the first opening portion 41 corresponding to the third color light-emitting element 303 is less than the width L3 of the third color light-emitting element 303.

It should be noted that, since the operating current of the first color light-emitting element 301is the highest, the width of the corresponding first opening portion 41 is set to be larger than the width of the first color light-emitting element 301. In this way, the luminance of the light-emitting element 30 is increased by increasing the width of the first opening portion 41, which is conducive to balancing the luminance differences of different light-emitting elements 30. Since the operating current of the third color light-emitting element 303 is the lowest, the width of the corresponding first opening portion 41 is set to be less than the width of the third color light-emitting element 303. In this way, the width of the first opening portions 41 is less than the width of the light-emitting elements 30, which is conducive shielding the metal structure of the driving array layer 20 by the first light-shielding layer 40, thereby reducing the reflectivity of the display panel 100. Since the operating current is intermediate of the second color light-emitting element 302, the width of the corresponding first opening portion 41 is set to be equal to the width of the second color light-emitting element 302.

In some embodiments of the present disclosure, the first color may be red, the second color may be green, and the third color may be blue. It should be noted that this example is merely to illustrate, but not to limit, the present disclosure.

Referring to FIG. 1 and FIG. 2, in an embodiment of the present disclosure, the first light-shielding layer 40 includes light-shielding portions 42, and at least part of the light-shielding portions 42 overlaps the light-emitting elements 30.

It should be noted that the light-shielding portions 42 overlap the light-emitting elements 30 means that, along a direction perpendicular to the display panel 100, orthographic projections of the light-shielding portions 42 on the substrate 10 overlap orthographic projections of the light-emitting elements 30 on the substrate 10.

In an embodiment, the first light-shielding layer 40 includes a plurality of light-shielding portions 42, and the light-shielding portions 42 are configured to shield the metal structure of the driving array layer 20, thereby reducing the reflectivity of the display panel 100. In an embodiment, at least part of the light-shielding portions 42 overlaps the light-emitting elements 30, which is conducive to shielding the metal structure overlapping the light-emitting elements 30 by the light-shielding portions 42, thereby reducing the reflectivity of the display panel 100.

Referring to FIG. 1 and FIG. 2, in some embodiments of the present disclosure, the overlapping width of the light-shielding portion 42 and the light-emitting element 30 is W, and 0 μm<W≤3 μm.

In an embodiment, since the edge of the light-emitting element 30 is relatively dim, the light-shielding portion 42 is configured to shield the edge of the light-emitting element 30. On the one hand, the effect on the luminance of the light-emitting element 30 is slight, and on the other hand, it is conducive to shielding the metal structure of the driving array layer 20, thereby reducing the reflectivity of the display panel 100. In an embodiment of the present disclosure, the light-shielding portion 42 shields the width of the light-emitting element 30, and the overlapping width W of the light-shielding portion 42 and the light-emitting element 30 is set to satisfy 0 μm<W≤3 μm. When the overlapping width W of the light-shielding portion 42 and the light-emitting element 30 satisfies W>3 μm, the light-emitting element 30 is shielded too much, which may cause a greater impact on the luminance of the light-emitting element 30 and affect the display effect of the display panel. Therefore, the overlapping width W of the light-shielding portion 42 and the light-emitting element 30 is set to satisfy 0 μm<W≤3 μm. In this way, the light-shielding portion 42 appropriately shields the edge of the light-emitting element 30, which is conducive to shielding the metal structure of the driving array layer 20, and reducing the reflectivity of the display panel 100, thereby improving the display effect of the display panel 100. In an embodiment of the present disclosure, the overlapping width of the light-shielding portion 42 and the light-emitting element 30 satisfies W=1 μm. In an embodiment of the present disclosure, the overlapping width of the light-shielding portion 42 and the light-emitting element 30 satisfies W=2 μm. In another embodiment of the present disclosure, the overlapping width of the light-shielding portion 42 and the light-emitting element 30 satisfies W=3 μm.

It should be noted that the overlapping width W of the light-shielding portion 42 and the light-emitting element 30 refers to the overlapping width of the light-shielding portion 42 and one edge of the light-emitting element 30.

Referring to FIG. 6 and FIG. 7, in an embodiment of the present disclosure, the width of the light-emitting element 30 in the first direction F1 is greater than the width of the light-emitting element 30 in the second direction F2, the first direction F1 and the second direction F2 intersect with each other, the first direction F1 is parallel to the plane of the display panel 100, and the second direction F2 is parallel to the plane of the display panel 100.

In the first direction F1, the overlapping width of the light-shielding portion 42 and the light-emitting element 30 is W1; and in the second direction F2, the overlapping width of the light-shielding portion 42 and the light-emitting element 30 is W2, where W1>W2.

In an embodiment, the width of the light-emitting element 30 in the first direction F1 is greater than the width of the light-emitting element 30 in the second direction F2, and the width of the area of the light-emitting element 30 with lower luminance in the first direction F1 is greater than the width of the area of the light-emitting element 30 with lower luminance in the second direction F2. Therefore, the overlapping width of the light-shielding portion 42 and the light-emitting element 30 in the first direction F1 is greater than the overlapping width of the light-shielding portion 42 and the light-emitting element 30 in the second direction F2. In this way, the area of the light-emitting element 30 with lower luminance is shielded, which is conducive to shielding the metal structure of the driving array layer 20, thereby reducing the reflectivity and improving the display effect of the display panel 100.

Referring to FIG. 9, in an embodiment of the present disclosure, the light-emitting elements 30 includes the first color light-emitting element 301 and the second color light-emitting element 302, and the operating current of the first color light-emitting element 301 is greater than the operating current of the second color light-emitting element 302.

In the first direction F1, the overlapping width of the light-shielding portion 42 and the first color light-emitting element 301 is r, and the overlapping width of the light-shielding portion 42 and the second color light-emitting element 302 is g. The first direction F1 is parallel to the plane of the display panel 100, where r<g.

In an embodiment, in order to improve the color richness of the display panel 100, the display panel 100 includes light-emitting elements 30 of multiple colors, and the light-emitting elements 30 include the first color light-emitting element 301 and the second color light-emitting element 302. The light-emitting elements 30 of different colors require different operating currents, and the operating current of the first color light-emitting element 301 is greater than the operating current of the second color light-emitting element 302. The operating current affects the power consumption of the display panel 100, which satisfies Power consumption=Operating current × Voltage. It can be seen that the greater the operating current, the higher the power consumption of the display panel 100. The operating current of the first color light-emitting element 301 is greater than the operating current of the second color light-emitting element 302. Therefore, the power consumption of the first color light-emitting element 301 is greater than the power consumption of the second color light-emitting element 302. Under the same power consumption, the luminance of the first color light-emitting element 301 is less than the luminance of the second color light-emitting element 302. In this embodiment, the overlapping width r of the light-shielding portion 42 and the first color light-emitting element 301 is set to be less than the overlapping width g of the light-shielding portion 42 and the second color light-emitting element 302. In this way, by reducing the width r of the light-shielding portion 42 shielding the first color light-emitting element 301, the first color light-emitting element 301 emits more light, and by reducing the overlapping width of the light-shielding portion 42 and the first color light-emitting element 301, the luminance of the first color light-emitting element 301 is increased, which is conducive to balancing the luminance differences of different light-emitting elements 30. The light-shielding portion 42 shields the metal structure of the driving array layer 20, which is conducive to reducing the reflectivity of the display panel 100, thereby improving the display effect of the display panel 100.

It should be noted that the display panel 100 may include light-emitting elements 30 of colors such as red, green, and blue, and the light-emitting elements 30 of different colors correspond to different operating currents. In some embodiments of the present disclosure, the first color is red and the second color is green. This example is merely to illustrate, but not limit, the present disclosure. For example, the first color may also be green and the second color may also be blue.

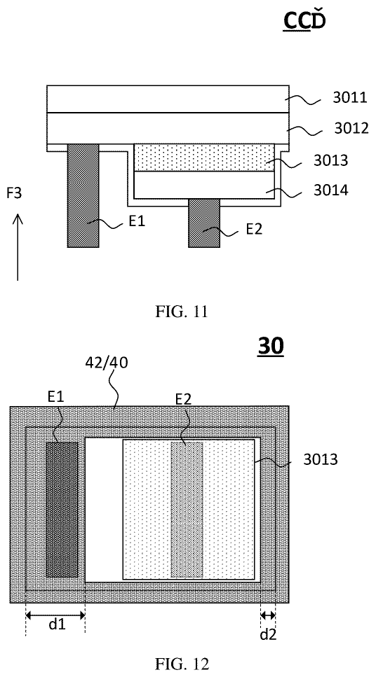

FIG. 11 is a schematic cross-sectional view of a light-emitting element along CC′ in FIG. 1 of the present disclosure. Referring to FIG. 1 and FIG. 11, in an embodiment of the present disclosure, the light-emitting element 30 includes an epitaxial layer 3011, a first semiconductor layer 3012, a quantum well layer 3013, and a second semiconductor layer 3014 arranged in a stacked manner; the first semiconductor layer 3012 is provided at a side of the epitaxial layer 3011, the quantum well layer 3013 is provided at a side of the first semiconductor layer 3012 away from the epitaxial layer 3011, and the second semiconductor layer 3014 is provided at a side of the quantum well layer 3013 away from the epitaxial layer 3011. Along the direction perpendicular to the display panel 100, an orthographic projection of the quantum well layer 3013 on the epitaxial layer 3011 is located within an orthographic projection of the first semiconductor layer 3012 on the epitaxial layer 3011. The light-emitting element 30 further includes a first electrode E1 and a second electrode E2, the first electrode E1 is electrically connected to the first semiconductor layer 3012, and the second electrode E2 is electrically connected to the second semiconductor layer 3014. Along the direction perpendicular to the display panel 100, the first electrode E1 does not overlap the quantum well layer 3013, and the second electrode E2 overlaps the quantum well layer 3013.

In an embodiment, a film layer structure of the light-emitting element 30 is provided. Along the direction perpendicular to the plane of the display panel 100 (third direction F3), the light-emitting element 30 includes the epitaxial layer 3011, the first semiconductor layer 3012, the quantum well layer 3013, and the second semiconductor layer 3014 that are arranged in a stacked manner. The area of the orthographic projection of the quantum well layer 3013 on the epitaxial layer 3011 in the third direction F3 is less than the area of the orthographic projection of the first semiconductor layer 3012 on the epitaxial layer 3011 in the third direction F3. That is, the quantum well layer 3013 and the first semiconductor layer 3012 do not completely overlap each other. The light-emitting element 30 further includes the first electrode E1 and the second electrode E2. The first electrode E1 is provided at a side of the first semiconductor layer 3012 away from the epitaxial layer 3011, and is electrically connected to the first semiconductor layer 3012. The first electrode E1 does not overlap the quantum well layer 3013 in the third direction F3. The second electrode E2 is provided at a side of the second semiconductor layer 3014 away from the quantum well layer 3013, and is electrically connected to the second semiconductor layer 3014. The second electrode E2 overlaps the quantum well layer 3013 in the third direction F3.

In a further embodiment of the present disclosure, the first semiconductor layer 3012 is a P-type semiconductor layer, the second semiconductor layer 3014 is an N-type semiconductor layer, the quantum well layer 3013 is provided between the first semiconductor layer 3012 and the second semiconductor layer 3014, and the holes provided by the first semiconductor layer 3012 and the electrons provided by the second semiconductor layer 3014 are recombined in the quantum well layer 3013 to realize light emission. It should be noted that this example is merely to illustrate the light emission principle of the light-emitting element 30, and is not to limit the light-emitting element 30.

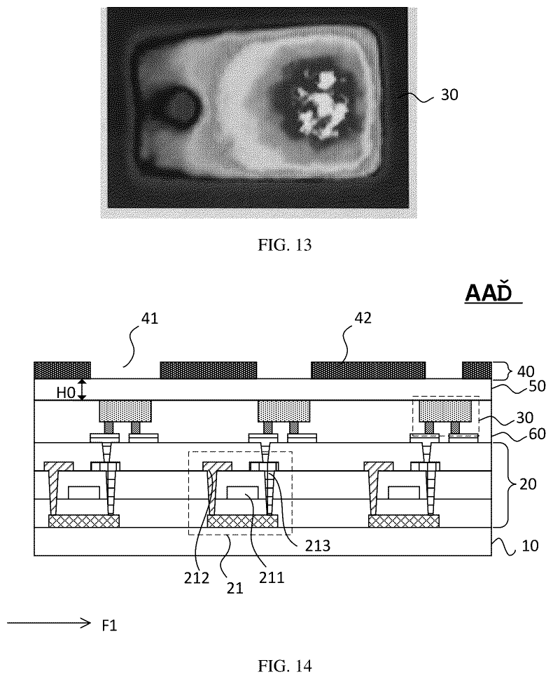

FIG. 12 is a schematic top view of a light-emitting element according to some embodiments of the present disclosure. FIG. 13 is a schematic diagram of luminous luminance of a light-emitting element according to some embodiments of the present disclosure. Referring to FIG. 1, and FIG. 11 to FIG. 13, it should also be noted that the luminous principle of the light-emitting element 30 is that holes and electrons recombine in the quantum well layer 3013 to realize light emission. Therefore, the emission intensity corresponding to the region of the quantum well layer 3013 is higher than that of other regions, and the quantum well layer 3013 is not located at the center of the light-emitting element 30. The structure of the light-emitting element 30 is not completely symmetrical, and its light emission is also asymmetric. FIG. 13 shows the asymmetry of the light emission of the light-emitting element 30. Based on this, in an embodiment of the present disclosure, along the direction from the first electrode E1 to the second electrode E2, the overlapping width of the light-shielding portion 42 and a side of the light-emitting element 30 close to the first electrode E1 is d1, and the overlapping width of the light-shielding portion 42 and a side of the light-emitting element 30 close to the second electrode E2 is d2, where d1>d2.

In an embodiment, the light-emitting element 30 includes the first electrode E1 and the second electrode E2. The first electrode E1 is electrically connected to the first semiconductor layer 3012, and the second electrode E2 is electrically connected to the second semiconductor layer 3014. The quantum well layer 3013 is provided between the first semiconductor layer 3012 and the second semiconductor layer 3014. The holes and electrons generated by the first semiconductor layer 3012 and the second semiconductor layer 3014 respectively are recombined in the quantum well layer 3013 to realize light emission. In the third direction F3, the first electrode E1 does not overlap the quantum well layer 3013, and the second electrode E2 overlaps the quantum well layer 3013. Therefore, the luminous intensity of the side of the light-emitting element 30 close to the first electrode E1 is lower than the luminous intensity of the side of the light-emitting element 30 close to the second electrode E2. Therefore, in this embodiment, the overlapping width of the light-shielding portion 42 and the side of the light-emitting element 30 close to the first electrode E1 is set to be greater than the overlapping width of the light-shielding portion 42 and the side of the light-emitting element 30 close to the second electrode E2. That is, the overlapping width of the light-shielding portion 42 and the side of the light-emitting element 30 with lower luminous intensity is greater than the overlapping width of the light-shielding portion 42 and the side of the light-emitting element 30 with higher luminous intensity. Such configuration is conducive to fully utilizing the light emitted by the light-emitting element 30, thereby reducing the power consumption of the display panel 100. The light-shielding portion 42 effectively shields the metal structure of the driving array layer 20, which is conducive to reducing the reflectivity of the display panel 100, thereby improving the display effect of the display panel 100.

FIG. 14 is a further schematic cross-sectional view taken along AA′ in FIG. 1 of the present disclosure. Referring to FIG. 1 and FIG. 14, in an embodiment of the present disclosure, the display panel 100 further includes a blocking layer 50. The blocking layer 50 is provided between the light-emitting element 30 and the first light-shielding layer 40. The blocking layer 50 is in direct contact with the light-emitting element 30 and the first light-shielding layer 40, respectively.

In an embodiment of the present disclosure, the display panel 100 includes the driving array layer 20, the light-emitting element 30, and the first light-shielding layer 40. The first light-shielding layer 40 is provided at the side of the light-emitting element 30 away from the substrate 10. The first light-shielding layer 40 is configured to shield the metal structure of the driving array layer 20, thereby reducing the reflectivity of the display panel 100. In the present disclosure, the distance H0 between the surface of the first light-shielding layer 40 on the side close to the light-emitting element 30 and the surface of the light-emitting element 30 on the side away from the substrate 10 is set to be greater than 0. That is, the first light-shielding layer 40 is not in direct contact with the light-emitting element 30, which facilitates removing the corresponding first light-shielding layer 40 above the light-emitting element 30, and reducing the influence of the first light-shielding layer 40 on the light-emitting element 30, thereby improving the display effect of the display panel 100. Regarding the fact that the first light-shielding layer 40 is not in direct contact with the light-emitting element 30, in an embodiment of the present disclosure, the blocking layer 50 is provided between the light-emitting element 30 and the first light-shielding layer 40, and is in direct contact with the light-emitting element 30 and the first light-shielding layer 40. In some embodiments of the present disclosure, the blocking layer 50 may be an organic layer or an inorganic layer, which is not specifically limited in the present disclosure. The blocking layer 50 is configured to prevent the first light-shielding layer 40 from directly contacting the light-emitting element 30 layer, thereby facilitating removing the corresponding first light-shielding layer 40 above the light-emitting element 30, and thus improving the display effect of the display panel 100.

Regarding the material of the blocking layer 50, in an embodiment of the present disclosure, the blocking layer 50 is made of photoresist. In an embodiment, the blocking layer 50 may be made of acrylic photoresist. In another embodiment of the present disclosure, the blocking layer 50 is formed using inkjet printing transparent ink. It should be noted that this example is merely to illustrate, but not to limit, the present disclosure. In actual use, suitable materials can be selected according to the needs.

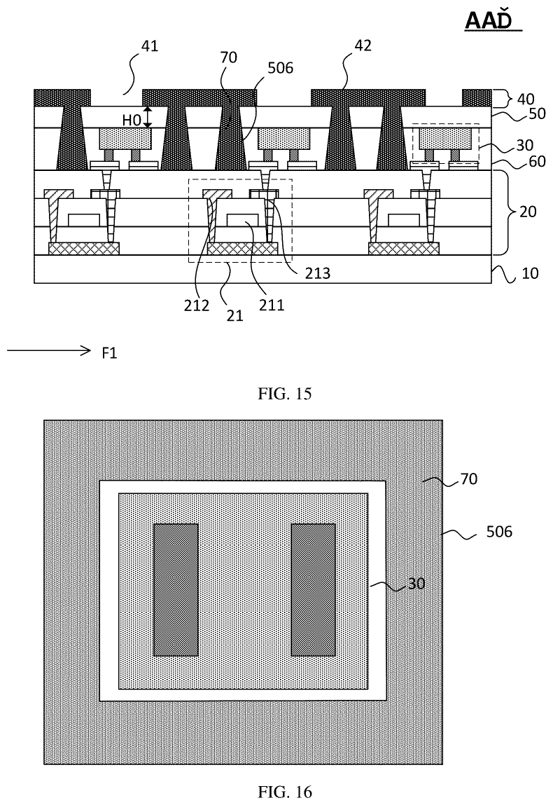

It should be noted that the blocking layer 50 is provided at the side of the light-emitting element 30 away from the substrate 10, and other film layers are provided between the blocking layer 50 and the driving array layer 20. FIG. 15 is a further schematic cross-sectional view taken along AA′ in FIG. 1 of the present disclosure. Referring to FIG. 1 and FIG. 15, in an embodiment of the present disclosure, the display panel 100 further includes a filling layer 60 and a second light-shielding layer 70. The filling layer 60 is provided between the driving array layer 20 and the blocking layer 50. The filling layer 60 and the blocking layer 50 include a recessed portion 506, and the second light-shielding layer 70 fills the recessed portion 506.

In an embodiment, the filling layer 60 is provided between the driving array layer 20 and the blocking layer 50. The filling layer 60 and the blocking layer 50 jointly cover the light-emitting elements 30 of the display panel 100 and the metal structure of the driving array layer 20. On the one hand, it is conducive to isolating water and oxygen, and protecting the light-emitting elements 30 and the driving circuit layer, thereby improving the stability of the display panel 100. On the other hand, after the light-emitting elements 30 are transferred, flattening is performed to prevent the first light-shielding layer 40 from directly contacting the layer of the light-emitting elements 30, thereby facilitating removing the corresponding first light-shielding layer 40 above the light-emitting element 30, and thus improving the display effect of the display panel 100. The blocking layer 50 and the filling layer 60 include the recessed portion 506, the display panel 100 further includes the second light-shielding layer 70, and the second light-shielding layer 70 fills the recessed portion 506. The second light-shielding layer 70 is formed around the light-emitting element 30 to surround it. The second light-shielding layer 70 covers the metal area around the light-emitting element 30 to prevent the light of the light-emitting element 30 from leaking to the metal structure of the driving array layer 20, improve the luminance fluctuation caused by light leakage, and improve the reliability of the display panel 100. In this way, the metal structure of the driving array layer 20 is further shielded, which is conducive to reducing the reflectivity of the display panel 100, improving the display effect of the display panel 100, and meanwhile, preventing the light of one light-emitting element 30 from being emitted to another light-emitting element 30, thereby avoiding the problem of light mixing between light-emitting elements 30 of different colors.

Referring to FIG. 1 and FIG. 15, in some embodiments of the present disclosure, the blocking layer 50 and the filling layer 60 include an organic material, and the blocking layer 50 and the filling layer 60 are formed by the same manufacturing process.

In an embodiment, the filling layer 60 and the blocking layer 50 jointly cover the light-emitting elements 30 of the display panel 100 and the metal structure of the driving array layer 20. On the one hand, it is conducive to isolating water and oxygen, and protecting the light-emitting elements 30 and the driving circuit layer, thereby improving the stability of the display panel 100. On the other hand, after the light-emitting elements 30 are transferred, flattening is performed to prevent the first light-shielding layer 40 from directly contacting the layer of the light-emitting elements 30, thereby facilitating the removal of the corresponding first light-shielding layer 40 above the light-emitting element 30, and thus improving the display effect of the display panel 100. The blocking layer 50 and the filling layer 60 may include the organic material. In an embodiment of the present disclosure, the filling layer 60 may be made of the same material and with the same process as the blocking layer 50, which is conducive to simplifying the manufacturing process and improving production efficiency. In another embodiment of the present disclosure, the filling layer 60 and the blocking layer 50 are manufactured by steps using different materials, which are not limited thereto in the present disclosure and can be selected according to actual needs.

FIG. 16 is a schematic top view of a light-emitting element and a second light-shielding layer according to some embodiments of the present disclosure. Referring to FIG. 1, FIG. 15 and FIG. 16, in an embodiment of the present disclosure, the recessed portion 506 does not overlap the light-emitting elements 30.

In an embodiment, the filling layer 60 and the blocking layer 50 are arranged to prevent the first light-shielding layer 40 from directly contacting the layer of the light-emitting elements 30, thereby facilitating the removal of the corresponding first light-shielding layer 40 above the light-emitting element 30, and thus improving the display effect of the display panel 100. The arrangement of the recessed portion 506 in the filling layer 60 and the blocking layer 50 is used to fill the second light-shielding layer 70, and the second light-shielding layer 70 is configured to shield the metal structure of the driving array layer 20. In this embodiment, the recessed portion 506 does not overlap the light-emitting elements 30, so that the second light-shielding layer 70 does not overlap the light-emitting elements 30, which is conducive to reducing the influence of the second light-shielding layer 70 on the luminance of the light-emitting elements 30, thereby improving the display effect of the display panel 100.

It should be noted that, in the third direction F3, the recessed portion 506 may penetrate through part of the blocking layer 50 and part of the filling layer 60, or may penetrate through all of the blocking layer 50 and all of the filling layer 60, which is not limited thereto in the present disclosure. When the recessed portion 506 runs though all of the blocking layer 50 and all of the filling layer 60, the second light-shielding layer 70 wraps the light-emitting elements 30, which is more conducive to preventing the light of the light-emitting element 30 from leaking to the metal structure of the driving array layer 20, and improving the luminance fluctuation caused by light leakage, thereby further improving the reliability of the display panel 100.

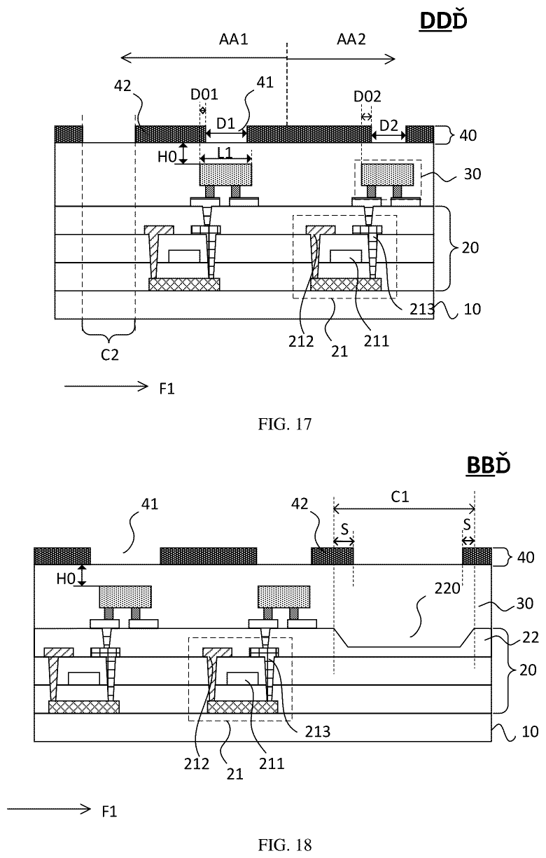

FIG. 17 is a schematic cross-sectional view taken along DD′ in FIG. 1 of the present disclosure. Referring to FIG. 1 and FIG. 17, in an embodiment of the present disclosure, the display panel 100 includes a first display area AA1 and a second display area AA2; the first light-shielding layer 40 includes the light-shielding portion 42, and at least part of the light-shielding portion 42 overlaps the light-emitting element 30; in the first display area AA1, the overlapping width of the light-shielding portion 42 and the light-emitting element 30 is D01; and in the second display area AA2, the overlapping width of the light-shielding portion 42 and the light-emitting element 30 is D02, where D01<D02.

In an embodiment, the first light-shielding layer 40 includes the light-shielding portion 42, and the light-shielding portion 42 is configured to shield the metal structure of the driving array layer 20, thereby reducing the reflectivity of the display panel 100. In an embodiment, at least part of the light-shielding portion 42 overlaps the light-emitting element 30, which is conducive to the light-shielding portion 42 shielding the metal structure overlapping the light-emitting element 30, thereby reducing the reflectivity of the display panel 100.

The display panel 100 includes the first display area AA1 and the second display area AA2. The overlapping width D01, in the first display area AA1, of the light-shielding portion 42 and the light-emitting element 30 is less than the overlapping width D02, in the second display area AA2, of the light-shielding portion 42 and the light-emitting element 30. Therefore, the luminance of the first display area is higher than that of the second display area, and the reflectivity of the second display area is lower than that of the first display area. By differentially designing the overlapping width of the light-shielding portion 42 and the light-emitting element 30 in different display areas of the display panel 100, different requirements of different display areas are met, which is conducive to improving the overall display effect of the display panel 100.

In some embodiments of the present disclosure, the first display area AA1 includes a sensor (not shown in the figures). In an embodiment of the present disclosure, the first display area AA1 includes a camera, and the camera is provided in the area C2. The sensor has a great influence on the luminous efficiency of the display panel 100. Therefore, it is necessary to improve the luminous efficiency of the display panel 100 by increasing the luminance of the first display area AA1. Therefore, the overlapping width D01, in the first display area AA1, of the light-shielding portion 42 and the light-emitting element 30 is set to be less than the overlapping width D02, in the second display area AA2, of the light-shielding portion 42 and the light-emitting element 30. It should be noted that this example is merely to illustrate, but not to limit, the present disclosure.

It should be noted that, in some embodiments of the present disclosure, in the first display area AA1, the light-shielding portion 42 does not overlap the light-emitting element 30. That is, the width D1 of the first opening portions 41 corresponding to the light-emitting element 30 is greater than the width L1 of the light-emitting element 30. Such configuration is more conducive to improving the luminance of the first display area, thereby improving the display effect of the display panel.

Referring to FIG. 1 and FIG. 2, in some embodiments of the present disclosure, the thickness of the first light-shielding layer 40 is h, where 1 μm≤h≤10 μm.

In an embodiment, the first light-shielding layer 40 is mainly used to shield the metal structure of the driving array layer 20, thereby reducing the reflectivity of the display panel 100. When the thickness h of the first light-shielding layer 40 satisfies h<1 μm, the thickness of the first light-shielding layer 40 is thin and the shielding effect is poor. When the thickness h of the first light-shielding layer 40 satisfies h>10 μm, the thickness of the first light-shielding layer 40 is thick, which on the one hand, affects the thickness of the display panel 100, and on the other hand, affects the luminous efficiency of the display panel 100. Therefore, the thickness h of the first light-shielding layer 40 is set to satisfy 1 μm≤h≤10 μm, which is conducive to effectively shielding the metal structure of the driving array layer 20, and reducing the influence of the light-shielding layer on the luminous efficiency of the display panel 100, thereby comprehensively improving the display effect of the display panel 100. In an embodiment of the present disclosure, the thickness h of the first light-shielding layer 40 satisfies h=2 μm. In an embodiment of the present disclosure, the thickness h of the first light-shielding layer 40 satisfies h=3 μm. In an embodiment of the present disclosure, the thickness h of the first light-shielding layer 40 satisfies h=5 μm. In an embodiment of the present disclosure, the thickness h of the first light-shielding layer 40 is set to satisfy 1 μm<h≤7 μm. In another embodiment of the present disclosure, the thickness h of the first light-shielding layer 40 is set to satisfy 3 μm≤h≤8 μm.

Referring to FIG. 1 and FIG. 2 again, according to an embodiment of the present disclosure, the display panel 100 includes the substrate 10, the driving array layer 20, the light-emitting element 30 and the first light-shielding layer 40. The driving array layer 20 is provided at the side of the substrate 10. The light-emitting element 30 is provided at the side of the driving array layer 20 away from the substrate 10. The driving array layer 20 includes a plurality of metal structures. In order to cover the metal structures and reduce the reflectivity of the display panel 100, the first light-shielding layer 40 is provided at the side of the light-emitting element 30 away from the substrate 10. Regarding the display panel 100 according to some embodiments of the present disclosure, the distance H0 between the surface of the first light-shielding layer 40 on the side close to the light-emitting element 30 and the surface of the light-emitting element 30 on the side away from the substrate 10 is greater than 0. That is, the first light-shielding layer 40 is not in direct contact with the light-emitting element 30. Such configuration is conducive to removing the first light-shielding layer 40 above the light-emitting element 30, and reducing the influence of the first light-shielding layer 40 on the light-emitting element 30, thereby improving the display effect of the display panel 100. Further, H0≥1 μm.

In an embodiments, H0 can affect the reflectivity of the display panel 100 at a large viewing angle. The greater H0 is, the more the luminance at the large viewing angle decreases, and the low the luminance at the large viewing angle is. Conversely, the less H0 is, the less the luminance at the large viewing angle decreases, and the higher the luminance at the large viewing angle is. When H0 satisfies H0<1 μm, the luminance at the large viewing angle is high, which is not conducive to the anti-peeping performance of the display panel 100. Therefore, the distance H0 between the surface of the first light-shielding layer 40 on the side close to the light-emitting element 30 and the surface of the light-emitting element 30 on the side away from the substrate 10 is set to satisfy H0>1 μm. Within this range, it can be set according to actual needs, which is conducive to improving the anti-peeping performance of the display panel 100. In an embodiment of the present disclosure, the distance H0 between the surface of the first light-shielding layer 40 on the side close to the light-emitting element 30 and the surface of the light-emitting element 30 on the side away from the substrate 10 satisfies H0=1 μm. In another embodiment of the present disclosure, the distance H0 between the surface of the first light-shielding layer 40 on the side close to the light-emitting element 30 and the surface of the light-emitting element 30 on the side away from the substrate 10 satisfies H0=3 μm. In an embodiment of the present disclosure, the distance H0 between the surface of the first light-shielding layer 40 on the side close to the light-emitting element 30 and the surface of the light-emitting element 30 on the side away from the substrate 10 satisfies H0=8 μm. In another embodiment of the present disclosure, the distance H0 between the surface of the first light-shielding layer 40 on the side close to the light-emitting element 30 and the surface of the light-emitting element 30 on the side away from the substrate 10 satisfies 4 μm≤H0≤7 μm.

FIG. 18 is a further schematic cross-sectional view taken along BB′ in FIG. 1 of the present disclosure. Referring to FIG. 18, in some embodiments of the present disclosure, the driving array layer 20 includes a plurality of transistors 21 and an insulating layer 22, and the insulating layer 22 covers the transistors 21. The driving array layer 20 includes a clearance area C1, and in the clearance area C1, the insulating layer 22 of the driving array layer 20 includes a groove 220. The overlapping width of the clearance area and the light-shielding portion 42 is S, where S≥1 μm.

In an embodiment, the display panel 100 includes the driving array layer 20, and the driving array layer 20 includes transistors 21 and an insulating layer 22 covering the transistors 21. The driving array layer 20 further includes the clearance area C1, and the clearance area C1 does not include circuit structures such as transistors 21 and other metal traces. In the clearance area C1, the insulating layer 22 includes the groove 220. In an embodiment, the overlapping width S of the light-shielding portion 42 and the clearance area C1 is set to satisfy S≥1 μm. When the overlapping width S of the light-shielding portion 42 and the clearance area C1 satisfies S<1 μm, the light-shielding portion 42 cannot effectively shield the transistors 21 adjacent to the clearance area C1, resulting in a problem of metal light leakage at the large viewing angle. Therefore, in some embodiments of the present disclosure, the overlapping width S of the clearance area C1 and the light-shielding portion 42 is set to satisfy S≥1 μm, which is conducive to effectively shielding the driving array layer 20 by the light-shielding portion 42, and improving the problem of metal light leakage at the large viewing angle, thereby improving the display effect of the display panel 100. In an embodiment of the present disclosure, the overlapping width S of the clearance area C1 and the light-shielding portion 42 satisfies S=2 μm. In an embodiment of the present disclosure, the overlapping width S of the clearance area C1 and the light-shielding portion 42 satisfies S=3 μm. In another embodiment of the present disclosure, the overlapping width S of the clearance area C1 and the light-shielding portion 42 satisfies S=5 μm. In another embodiment of the present disclosure, the overlapping width S of the clearance area C1 and the light-shielding portion 42 satisfies 1.5 μm≤S≤2.5 μm.

It should be noted that the clearance area C1 may be a transparent area in the transparent display panel, in which no light-emitting element is included, and the driving array layer does not include metal structures such as transistors and first traces. This example is merely to illustrate, but not to limit, the present disclosure.

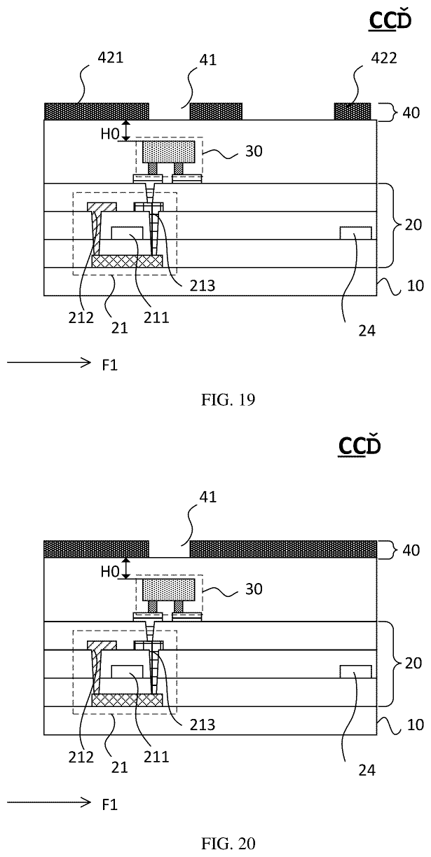

FIG. 19 is a further schematic cross-sectional view taken along CC′ in FIG. 1 of the present disclosure. Referring to FIG. 1 and FIG. 19, in an embodiment of the present disclosure, the first light-shielding layer 40 includes a first light-shielding portion 421 and a second light-shielding portion 422, the driving array layer 20 includes a plurality of transistors 21 and a plurality of first traces 24, the first light-shielding portion 421 overlaps the transistors 21, the second light-shielding portion 422 overlaps the first traces 24, and the first light-shielding portion 421 and the second light-shielding portion 422 are independent of each other.

In an embodiment, the driving array layer 20 includes the transistors 21 and the first traces 24, and the first light-shielding layer 40 is configured to shield the transistors 21 and the first traces 24, thereby reducing the reflectivity of the display panel 100. The first light-shielding layer 40 includes the first light-shielding portion 421 and the second light-shielding portion 422, and the first light-shielding portion 421 is configured to shield the transistors 21, and the first light-shielding portion 421 is arranged to overlap the transistors 21. The second light-shielding portion 422 is configured to shield the first traces 24 and overlap the transistors 21. In this way, in some embodiments of the present disclosure, the first light-shielding portion 421 and the second light-shielding portion 422 are configured to shield the transistors 21 and the first traces 24, respectively, which is conducive to effectively shielding the metal structure of the driving array layer 20, thereby reducing the reflectivity of the display panel 100 and improving the display effect of the display panel 100.

Referring to FIG. 19 again, in an embodiment of the present disclosure, the width of the second light-shielding portion 422 is less than the width of the first light-shielding portion 421.

In an embodiment, the display panel 100 includes the first light-shielding layer 40, and the first light-shielding layer 40 includes the first light-shielding portion 421 and the second light-shielding portion 422. The driving array layer 20 includes the transistors 21 and the first traces 24. In the third direction F3, the first light-shielding layer 40 overlaps the transistors 21 to shield the transistors 21, and the second light-shielding layer 70 overlaps the first traces 24 to shield the first traces 24, which is conducive to effectively shielding the metal structure of the driving array layer 20, thereby reducing the reflectivity of the display panel 100 and improving the display effect of the display panel 100. Since the width of the transistors 21 is usually greater than the width of the first traces 24, the width of the second light-shielding portion is set to be less than the width of the first light-shielding portion in this embodiment, which is more conducive to shielding the transistors 21 and the first traces 24. Meanwhile, unnecessary shielding are reduced, which is conducive to increasing the opening area of the first light-shielding layer 40, thereby improving the display effect of the display panel 100.

Referring to FIG. 1 and FIG. 2, in an embodiment of the present disclosure, the display panel 100 includes a gate driving circuit and a pixel driving circuit, and the first light-shielding portion 421 overlaps the gate driving circuit and the pixel driving circuit.

It should be noted that the gate driving circuit and the pixel driving circuit are not fully shown in the drawings. The gate driving circuit and the pixel driving circuit are located in the driving array layer 20. In some embodiments of the present disclosure, the first light-shielding layer 40 is configured to shield the metal structure of the driving array layer 20.

In an embodiment, the display panel 100 includes the gate driving circuit and the pixel driving circuit. The pixel driving circuit is configured to drive the light-emitting elements 30 to emit light, and the gate driving circuit is configured to provide a scanning signal to the pixel driving circuit. The first light-shielding portion 421 overlaps the gate driving circuit and the pixel driving circuit to shield the metal structure of the driving array layer 20, which is conducive to reducing the reflectivity of the display panel 100 and improving the display effect of the display panel 100.

It should be noted that the pixel driving circuit may be a plurality of pixel driving circuits arranged in an array, and the pixel driving circuit receives the scanning signal provided by the gate driving circuit and is turned on or off under the action of the scanning signal to provide a light-emitting signal to the light-emitting elements 30, or to stop providing the light-emitting signal to the light-emitting elements 30. The pixel driving circuit may include one or more transistors, and the drawings of the present disclosure are illustrated by taking the pixel driving circuit including one transistor as an example. The pixel driving circuit may also be a “2TIC” circuit including two transistors and one storage capacitor, or a “7TIC” circuit. “T” represents the transistor, and “C” represents the storage capacitor. In the present disclosure, the specific structure of the pixel driving circuit is not limited, and can be designed according to actual needs and the type of the display panel 100. Further, the transistor may include a source, a drain and a gate. The control signal is input through the gate, the channel area between the source and the drain is turned on, and a path is formed between the source and the drain. The electrical signal can be written into the drain through the source and the channel area.

FIG. 20 is a further schematic cross-sectional view taken along CC′ in FIG. 1 of the present disclosure. Referring to FIG. 20, in an embodiment of the present disclosure, the first light-shielding layer 40 includes a plurality of first opening portions 41, and the first opening portions 41 only overlap the light-emitting elements 30.

In an embodiment, the display panel 100 includes the first light-shielding layer 40, and the first light-shielding layer 40 is configured to shield the metal structure of the driving array layer 20, which is conducive to reducing the reflectivity of the display panel 100. In an embodiment, the first opening portion 41 of the first light-shielding layer 40 only overlaps the light-emitting elements 30. That is, the first opening portion 41 is only arranged above the light-emitting elements 30. Such configuration is more conducive to shielding the driving array layer 20, and reducing the reflectivity of the display panel 100, therefore improving the display effect of the display panel 100.

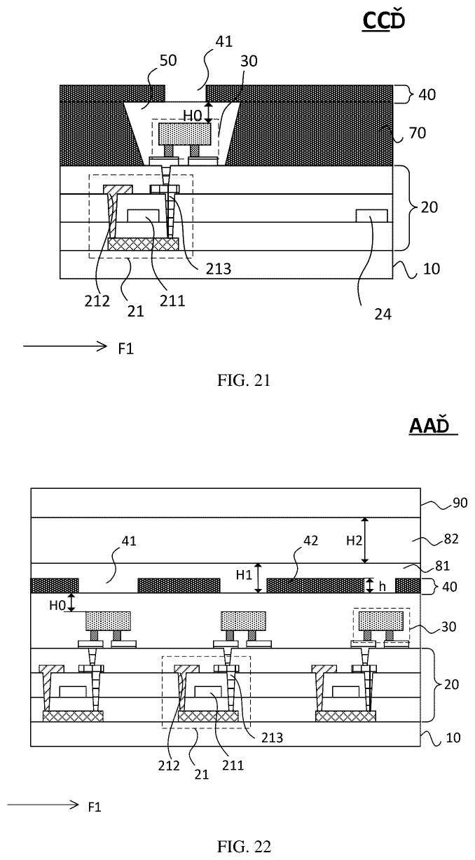

FIG. 21 is a further schematic cross-sectional view taken along CC′ in FIG. 1 of the present disclosure. Referring to FIG. 1 and FIG. 21, in an embodiment of the present disclosure, the display panel further includes the blocking layer 50 and the second light-shielding layer 70. The blocking layer 50 is provided between the driving array layer 20 and the first light-shielding layer 40, and the blocking layer 50 is in direct contact with the light-emitting elements 30 and the first light-shielding layer 40, respectively, and wraps the light-emitting elements 30.

The second light-shielding layer 70 is provided at the side of the first light-shielding layer 40 close to the light-emitting element 30. The second light-shielding layer 70 is in direct contact with the driving array layer 20 and the first light-shielding layer 40, respectively. The second light-shielding layer 70 is at least provided between adjacent light-emitting elements 30.

In an embodiment, the display panel 100 includes the blocking layer 50, the first light-shielding layer 40 and the second light-shielding layer 70. The first light-shielding layer 40 is provided at the side of the light-emitting element 30 away from the substrate 10. The blocking layer 50 is in direct contact with the light-emitting elements 30 and wraps the light-emitting elements 30, such that the light-emitting elements 30 are not in direct contact with the first light-shielding layer 40. The first opening portions 41 only overlap the light-emitting elements 30, which facilitates the removal of the first light-shielding layer 40 above the light-emitting elements 30 when forming the first opening portions 41, and reducing the influence of the first light-shielding layer 40 on the light-emitting elements 30, thereby improving the display effect of the display panel 100. The first light-shielding layer 40 effectively shields the driving array layer 20, which is conducive to reducing the reflectivity of the display panel 100. In an embodiment, the second light-shielding layer 70 is further provided between the driving array layer 20 and the first light-shielding layer 40, and covers the metal area around the light-emitting elements 30 to prevent the light emitted by the light-emitting elements 30 from leaking to the metal structure of the driving array layer 20, thereby improving the luminance fluctuation caused by light leakage and improving the reliability of the display panel 100. In this way, the metal structure of the driving array layer 20 is further shielded, which is conducive to reducing the reflectivity of the display panel 100 and improving the display effect of the display panel 100.

Referring to FIG. 1 and FIG. 21 again, in an embodiment of the present disclosure, the first light-shielding layer 40 and the second light-shielding layer 70 are integrally formed.

It should be noted that the first light-shielding layer 40 and the second light-shielding layer 70 are integrally formed in the same process, which is conducive to simplifying the manufacturing process of the display panel 100 and improving production efficiency.

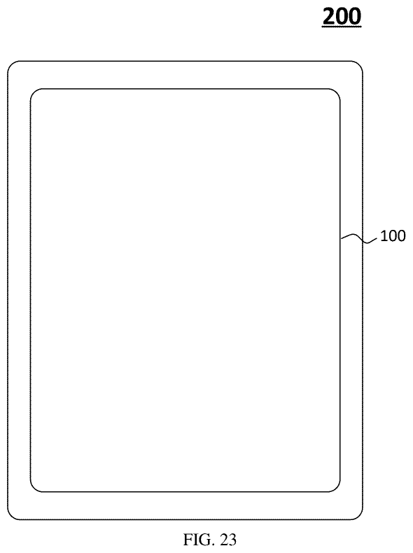

FIG. 22 is a further schematic cross-sectional view taken along AA′ in FIG. 1 of the present disclosure. Referring to FIG. 1 and FIG. 22, in some embodiments of the present disclosure, the display panel 100 further includes a transparent encapsulation layer 81. The transparent encapsulation layer 81 is provided at the side of the first light-shielding layer 40 away from the substrate 10.

In an embodiment, the transparent encapsulation layer 81 may be further provided at the side of the first light-shielding layer 40 away from the substrate 10. The transparent encapsulation layer 81 is configured to encapsulate and isolate water and oxygen, which is conducive to improving the reliability of the display panel 100. It should be noted that the transparent encapsulation layer 81 is in direct contact with the first light-shielding layer 40 and the blocking layer 50. The transparent encapsulation layer 81 may be made of the same material as the blocking layer 50, which is conducive to reducing the types of materials used in the display panel 100. This example is merely to illustrate, but not to limit, the present disclosure.

Referring to FIG. 1 and FIG. 22 again, regarding the thickness of the transparent encapsulation layer 81, in an embodiment of the present disclosure, the thickness of the transparent encapsulation layer 81 is greater than the thickness of the first light-shielding layer 40. In this way, the transparent encapsulation layer 81 can cover the first light-shielding layer 40 and the display area of the display panel 100, which is further conducive to isolating water and oxygen and protecting the display panel 100.

Referring to FIG. 1 and FIG. 22 again, in some embodiments of the present disclosure, the thickness of the transparent encapsulation layer 81 is H1, where H1>1 μm. Such configuration is conducive to the transparent encapsulation layer 81 covering the first light-shielding layer 40 and the display area of the display panel 100, and is more conducive to improving the reliability of the display panel 100. In an embodiment of the present disclosure, the thickness h of the first light-shielding layer 40 satisfies h=1 μm, and the thickness H1 of the transparent encapsulation layer 81 satisfies H1=2 μm. In another embodiment of the present disclosure, the thickness h of the first light-shielding layer 40 satisfies h=2 μm, and the thickness H1 of the transparent encapsulation layer 81 satisfies H1=4 μm. In another embodiment of the present disclosure, the thickness h of the first light-shielding layer 40 satisfies h=3 μm, and the thickness H1 of the transparent encapsulation layer 81 satisfies H1=4 μm. This example is merely to illustrate, but not to limit, the present disclosure.

Referring to FIG. 1 and FIG. 22 again, in some embodiments of the present disclosure, the display panel 100 further includes a transparent adhesive layer 82 and a cover plate 90. The transparent adhesive layer 82 is provided at a side of the transparent encapsulation layer 81 away from the substrate 10. The cover plate 90 is provided at a side of the transparent adhesive layer 82 away from the substrate 10. The transparent adhesive layer 82 is in direct contact with the cover plate 90.

In an embodiment, the display panel 100 further includes the cover plate 90, and the cover plate 90 is bonded to the side of the transparent encapsulation layer 81 away from the substrate 10 through the transparent adhesive layer 82. In an embodiment of the present disclosure, the transparent adhesive layer 82 includes optically clear adhesive (OCA). OCA is an adhesive used for bonding transparent optical elements, which has high transparency, low haze and good optical properties, which can bond the optical materials, and meanwhile minimize the refraction, reflection and scattering of light while bonding optical materials, thereby ensuring the clarity and transmittance of the optical system. The transparent adhesive layer 82 includes OCA, which is conducive to improving the display effect of the display panel 100.

Referring to FIG. 1 and FIG. 22, in some embodiments of the present disclosure, the thickness of the transparent adhesive layer 82 is H2, where 50 μm≤H2≤500 μm.

In an embodiment, the display panel 100 further includes a driver chip, and the driver chip is provided at a side of the display area of the display panel 100. When the thickness H2 of the transparent adhesive layer 82 satisfies H2<50 μm, the thickness of the transparent adhesive layer 82 is relatively thin, and the total thickness of the display area of the display panel 100 may be less than the thickness of the driver chip, which is not conducive to the bonding of the cover plate 90. When the thickness H2 of the transparent adhesive layer 82 satisfies H2>500 μm, the thickness of the transparent adhesive layer 82 is relatively thick, which is not conducive to the thinning of the display panel 100. Therefore, the thickness H2 of the transparent adhesive layer 82 is set to satisfy 50 μm≤H2≤500 μm. Such configuration is conducive to both the thinning of the display panel 100 and the bonding of the cover plate 90. In an embodiment of the present disclosure, the thickness H2 of the transparent adhesive layer 82 satisfies H2=60 μm. In another embodiment of the present disclosure, the thickness H2 of the transparent adhesive layer 82 satisfies H2=66 μm. In another embodiment of the present disclosure, the thickness H2 of the transparent adhesive layer 82 satisfies H2=100 μm. In another embodiment of the present disclosure, the thickness H2 of the transparent adhesive layer 82 satisfies 65 μm≤H2≤200 μm. In another embodiment of the present disclosure, the thickness H2 of the transparent adhesive layer 82 satisfies 80 μm≤H2≤400 μm.

Based on the same inventive concept, an embodiment of the present disclosure provides a display apparatus. FIG. 23 is a schematic diagram of a display apparatus according to some embodiments of the present disclosure. Referring to FIG. 23, a display apparatus 23 includes the display panel 100 according to some embodiments of the present disclosure.

It should be noted that the embodiment of the display apparatus 200 according to the embodiment of the present disclosure can refer to the embodiments of the display panel 100 described above, which will not be elaborated in the present disclosure. The display apparatus 200 according to some embodiments of the present disclosure may be: a mobile phone, a tablet computer, a television, a touch controller, a laptop computer, a navigator, or any other product or component with a display function.

It can be seen from the above embodiments that the display panel and display apparatus according to some embodiments of the present disclosure can achieve at least the following beneficial effects.

The present disclosure provide a display panel and a display apparatus. The display panel includes a substrate, a driving array layer, a light-emitting element and a first light-shielding layer. The driving array layer is provided at a side of the substrate. The light-emitting element is provided at a side of the driving array layer away from the substrate. The first light-shielding layer is provided at a side of the light-emitting element away from the substrate. In some embodiments of the present disclosure, a distance between a surface of the first light-shielding layer on a side close to the light-emitting element and a surface of the light-emitting element on a side away from the substrate is set to be greater than 0. That is, the first light-shielding layer is not in direct contact with the light-emitting element, which facilitates the removal of the corresponding first light-shielding layer above the light-emitting element, and reducing the influence of the first light-shielding layer on the light-emitting element, thereby improving the display effect of the display panel.

It should be noted that, in this specification, relational terms such as “first” and “second” are merely used to distinguish one entity or operation from another entity or operation, and do not necessarily require or imply any actual relationship or sequence between these entities or operations. In addition, terms such as “include”, “comprise” or any other variations thereof are intended to cover a non-exclusive inclusion, thus a process, method, item or device including a series of elements includes not only those elements, but also other elements not explicitly listed, or elements inherent in such the process, method, item or device. Without further limitations, an element defined by the statement “including one” does not preclude the presence of another identical element in a process, method, article, or device that includes the element.

The above contents describe specific embodiments of the present disclosure, such that those skilled in the art can understand or implement the present disclosure. Various modifications to these embodiments will be apparent to those skilled in the art, and the general principles defined herein may be implemented in other embodiments without departing from the spirit or scope of the present disclosure. Accordingly, the present disclosure will not be limited to the embodiments described herein, and should be interpreted to the broadest scope in conformity with the principles and innovations disclosed in the present disclosure.

What is claimed is:

1. A display panel, comprising:
a substrate;
a driving array layer provided at a side of the substrate;
a light-emitting element provided at a side of the driving array layer away from the substrate; and
a first light-shielding layer provided at a side of the light-emitting element away from the substrate;
wherein a distance between a surface of the first light-shielding layer close to the light-emitting element and a surface of the light-emitting element away from the substrate is H0, wherein H0>0.

2. The display panel according to claim 1, wherein the first light-shielding layer comprises a plurality of first opening portions, and at least one of the plurality of first opening portions overlaps the light-emitting element;
along a first direction and/or a second direction, a width of at least part of the first opening portions is greater than a width of the light-emitting element; and/or, the width of at least part of the first opening portions is equal to the width of the light-emitting element; and/or, the width of at least part of the first opening portions is less than the width of the light-emitting element;
the first direction and the second direction are parallel to a plane of the display panel; and the first direction and the second direction intersect with each other.

3. The display panel according to claim 2, wherein in the first direction, the width of at least part of the first opening portions is greater than the width of the light-emitting element; and in the second direction, the width of at least part of the first opening portions is equal to the width of the light-emitting element.

4. The display panel according to claim 2, wherein in the first direction, the width of at least part of the first opening portions is greater than the width of the light-emitting element; and in the second direction, the width of at least part of the first opening portions is greater than the width of the light-emitting element.

5. The display panel according to claim 2, wherein in the first direction, the width of at least part of the first opening portions is less than the width of the light-emitting element; and in the second direction, the width of at least part of the first opening portions is less than the width of the light-emitting element.

6. The display panel according to claim 5, wherein the width of the light-emitting element in the first direction is x1, and the width of the light-emitting element in the second direction is y1; wherein x1>y1;
wherein the width of the first opening portions in the first direction is x2, and the width of the first opening portions in the second direction is y2; wherein x2>y2; and
wherein x1−x2>y1−y2.

7. The display panel according to claim 6, wherein x1/y1≥x2/y2.

8. The display panel according to claim 2, wherein the light-emitting element comprises a first color light-emitting element and a second color light-emitting element, and an operating current of the first color light-emitting element is greater than an operating current of the second color light-emitting element;
in the first direction, the width of the first opening portion corresponding to the first color light-emitting element is D1, and the width of the first opening portion corresponding to the second color light-emitting element is D2; and
in the first direction, a width of the first color light-emitting element is L1, and a width of the second color light-emitting element is L2;
wherein D1>D2.

9. The display panel according to claim 8,
wherein D1>L1 and D2>L2; or
wherein D1<L1 and D2<L2.

10. The display panel according to claim 8, wherein the light-emitting element further comprises a third color light-emitting element, and an operating current of the third color light-emitting element is less than the operating current of the second color light-emitting element; and
in the first direction, a width of the first opening portion corresponding to the third color light-emitting element is D3, and a width of the third color light-emitting element is L3;
wherein D1>L1, D2=L2 and D3<L3.

11. The display panel according to claim 1, wherein the first light-shielding layer comprises a light-shielding portion, and at least part of the light-shielding portion overlaps the light-emitting element.

12. The display panel according to claim 11, wherein a width of the light-emitting element along a first direction is greater than a width of the light-emitting element along a second direction, the first direction and the second direction intersect with each other, the first direction is parallel to the plane of the display panel, and the second direction is parallel to the plane of the display panel; and
in the first direction, an overlapping width of the light-shielding portion and the light-emitting element is W1; and in the second direction, an overlapping width of the light-shielding portion and the light-emitting element is W2; wherein W1>W2.

13. The display panel according to claim 11, wherein the light-emitting element comprises a first color light-emitting element and a second color light-emitting element, and an operating current of the first color light-emitting element is greater than an operating current of the second color light-emitting element; and
along a first direction, an overlapping width of the light-shielding portion and the first color light-emitting element is r, and an overlapping width of the light-shielding portion and the second color light-emitting element is g, and the first direction is parallel to the plane of the display panel;
wherein r<g.

14. The display panel according to claim 11, wherein the light-emitting element comprises an epitaxial layer, a first semiconductor layer, a quantum well layer and a second semiconductor layer that are arranged in a stacked manner;
the first semiconductor layer is provided at a side of the epitaxial layer, the quantum well layer is provided at a side of the first semiconductor layer away from the epitaxial layer, and the second semiconductor layer is provided at a side of the quantum well layer away from the epitaxial layer;
along a direction perpendicular to the display panel, an orthographic projection of the quantum well layer on the epitaxial layer is located within an orthographic projection of the first semiconductor layer on the epitaxial layer;
the light-emitting element further comprises a first electrode and a second electrode, the first electrode is electrically connected to the first semiconductor layer, and the second electrode is electrically connected to the second semiconductor layer; and
along the direction perpendicular to the display panel, the first electrode does not overlap the quantum well layer, and the second electrode overlaps the quantum well layer.

15. The display panel according to claim 14, wherein along a direction from the first electrode to the second electrode, an overlapping width of the light-shielding portion and a side of the light-emitting element close to the first electrode is d1, and an overlapping width of the light-shielding portion and a side of the light-emitting element close to the second electrode is d2; wherein d1>d2.

16. The display panel according to claim 1, further comprising a blocking layer,
wherein the blocking layer is provided between the light-emitting element and the first light-shielding layer, and the blocking layer is in direct contact with the light-emitting element and the first light-shielding layer.

17. The display panel according to claim 16, further comprising a filling layer and a second light-shielding layer,
wherein the filling layer is provided between the driving array layer and the blocking layer, the filling layer and the blocking layer share a recessed portion, and the second light-shielding layer fills the recessed portion.

18. The display panel according to claim 1, further comprising a first display area and a second display area;
wherein the first light-shielding layer comprises a light-shielding portion, and at least part of the light-shielding portion overlaps the light-emitting element; and
wherein in the first display area, an overlapping width of the light-shielding portion and the light-emitting element is D01; and in the second display area, an overlapping width of the light-shielding portion and the light-emitting element is D02; wherein D01<D02.

19. The display panel according to claim 1, wherein the first light-shielding layer comprises a plurality of first opening portions, and one of the plurality of first opening portions only overlaps the light-emitting element;
wherein the display panel further comprises a blocking layer and a second light-shielding layer,
wherein the blocking layer is provided between the driving array layer and the first light-shielding layer, and the blocking layer is in direct contact with the light-emitting element and the first light-shielding layer, respectively, and is configured to wrap the light-emitting element; and
wherein the second light-shielding layer is provided at a side of the first light-shielding layer close to the light-emitting element, the second light-shielding layer is in direct contact with the driving array layer and the first light-shielding layer, respectively, and the second light-shielding layer is at least located between adjacent light-emitting elements.

20. A display apparatus, comprising a display panel, wherein the display panel comprises:
a substrate;
a driving array layer provided at a side of the substrate;
a light-emitting element provided at a side of the driving array layer away from the substrate; and
a first light-shielding layer provided at a side of the light-emitting element away from the substrate;
wherein a distance between a surface of the first light-shielding layer on a side close to the light-emitting element and a surface of the light-emitting element on a side away from the substrate is H0, wherein H0>0.
